(19) United States
(12) Patent Application Publication
(10) Pub. No.: US 2005/0152189 A1
(43) Pub. Date: Jul. 14, 2005

(54) Display device

(75) Inventors: Kyung-Wol Kim, Seoul (KR); Yong-Weon Jeon, Suwon-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/035,596

(22) Filed: Jan. 13, 2005

(30) Foreign Application Priority Data
Jan. 14, 2004 (KR) 2004-2670

(51) Int. Cl. G11C 16/04

(52) U.S. Cl. 365/185.29

(57) ABSTRACT

A display device includes source drivers connected to a timing controller in a serial cascade. First through third buses are connected between the timing controller and a first source driver of source drivers. In a first period of time, a clock signal is transmitted via the first bus, a first operation control signal is transmitted via the second bus, a second operation control signal is transmitted via the third bus, and a polarity control signal is transmitted via the third bus. In a second period of time, the clock signal is transmitted via the first bus, the first operation control signal is transmitted via the second bus, and the second operation control signal is transmitted via the third bus. Source drivers generate a data initiation signal and a load signal using a combination of the logic levels of the operation control signals during each period.

This application claims the priority of Korean Patent Application No. 2004-2670, filed on Jan. 14, 2004, in the Korean Intellectual Property Office, the disclosure of which is incorporated herein in its entirety by reference.

### BACKGROUND OF THE INVENTION

1. Technical Field

The present invention relates to a display device, and more particularly, to a display device with a reduced number of buses connected between a timing controller and a plurality of source drivers.

2. Description of Related Art

FIG. 1 is a block diagram of a thin film transistor liquid crystal display (hereinafter “TFT-LCD”) 10. Referring to FIG. 1, the TFT-LCD 10 includes a display panel 12, a source driver block 14, a gate driver block 16, a timing controller 18, and a power source 20.

The display panel 12 includes a plurality of data lines S₁ through S_{N}, a plurality of scan lines or gate lines G₁ through G_{M}, and a plurality of pixel electrodes (not shown). N and M are integers greater than 1.

Thin Film Transistors (TFTs) can be connected between data lines and pixel electrodes. A gate line of a TFT is connected to a scan line, the TFT's source electrode is connected to a data line, and its drain electrode is connected to a pixel electrode.

The source driver block 14 includes a plurality of source drivers (not shown). When display data output from the timing controller 18, and at least one voltage generated by the power source 20 are applied to the source driver block 14, the source driver block 14 drives the data lines S₁ through S_{N} of the display panel 12. Display data includes DATA and control signals, such as a clock signal CLK, a data initiation signal DIO, a load signal LOAD, and a polarity control signal POL.

When a horizontal synchronization signal, a vertical synchronization signal, and the display data DATA are input to the timing controller 18, the timing controller 18 generates the signals CLK, DIO, DATA, LOAD, and POL, and outputs the signals CLK, DIO, DATA, LOAD, and POL to the source driver block 14 via corresponding buses 21, 22, 23, 24, and 25.

FIG. 2 is a timing diagram illustrating the operation of the TFT-LCD of FIG. 1. Referring to FIGS. 1 and 2, the clock signal CLK is transmitted to the source driver block 14 via the bus 21. The data initiation signal DIO is transmitted to the source driver block 14 via the bus 22. The display data DATA is transmitted to the source driver block 14 via the bus 23 with a plurality of data lines D00 through Dxx (xx is an integer greater than or equal to 1). The load signal LOAD is transmitted to the source driver block 14 via the bus 24. The polarity control signal POL is transmitted to the source driver block 14 via the bus 25.

A data inversion signal INV may be transmitted to the source driver block 14 via a bus (not shown) connected between the timing controller 18 and the source driver block 14.

The clock signal CLK is also referred to as a dot clock signal. The data initiation signal DIO indicates a point at which generation of the display data DATA, which is also referred to as RGB data, begins.

A data latch or register (not shown) of the source driver block 14 receives and stores the display data DATA in synchronization with a rising edge and a falling edge of the input clock signal CLK after the data initiation signal DIO transits from a logic low to a logic high.

The load signal LOAD is activated, or goes high, after the display data DATA is completely stored in the data latch or register. The source driver block 14 converts digital display data DATA stored in the data latch into analog display data DATA. The source driver block 14 outputs converted analog display data DATA to the data lines S₁ through S_{N} of the display panel 12 in response to the activated load signal LOAD so as to drive the data lines S₁ through S_{N}.

The polarity of the display data DATA output to the data lines S₁ through S_{N} is determined by the polarity control signal POL. The data inverse signal INV is used to invert the display data DATA.

The gate driver block 16 includes a plurality of gate drivers (not shown). The gate driver block 16 consecutively drives the scan lines G₁ through G_{M} of the display panel 12 when the control signals CLK, DIO, LOAD, and POL output from the timing controller 18 and at least one voltage supplied from the power source 20 are applied to the gate driver block 16.

The timing controller 18 controls the operations of the source driver block 14, the gate driver block 16, and the power source 20, set by a host computer (not shown).

The power source 20 generates a voltage for driving the display panel 12 and various voltages, such as gray scale voltages, and applies the generated voltages to the display panel 12, the source driver block 14, and the gate driver block 16.

Referring to FIGS. 1 and 2, the buses 21, 22, 23, 24, and 25 through which the signals CLK, DIO, DATA, LOAD, and POL are transmitted to the source driver block 14, are connected between the timing controller 18 and the source driver block 14 so as to input the display data DATA to the display panel 12.

However, installation of the buses between a timing controller and a source driver block increases the area used by wiring and causes a display device to consume current. Further, the buses may generate electromagnetic interference (EMI).

### SUMMARY OF THE INVENTION

According to an embodiment of the present disclosure, a display device comprises a first bus transmitting a clock signal output from a timing controller to a source driver, a second bus transmitting a first operation control signal output from the timing controller to the source driver, and a data bus having a plurality of data lines transmitting display data output from the timing controller to the source driver. The timing controller outputs control signals, which control the source driver, to the source driver via the second bus and at least one of the plurality of data lines in a predetermined period of time.

The timing controller outputs a second operation control signal to the source driver via a first data line of the plurality of data lines, the second operation control signal having a logic level maintained to be equivalent to a logic level of the first operation control signal in the predetermined period of time. The source driver latches the display data in response to the first and second operation control signals.

The timing controller outputs a polarity control signal to the source driver via a second data line of the plurality of data lines in the predetermined period of time, and the source driver controls the polarity of the display data to be output, in response to the polarity control signal.

The timing controller outputs a second operation control signal to the source driver via the first data line of the plurality of data lines, the second operation control signal having a logic level maintained to be different from a logic level of the first operation control signal in the predetermined period of time. The source driver outputs display data in response to the polarity control signal and the first and second operation control signals.

According to an embodiment of the present disclosure, a display device comprises a first bus transmitting a clock signal output from a timing controller to a source driver, a second bus transmitting a first operation control signal output from the timing controller to the source driver, and a third bus transmitting a data inversion signal output from the timing controller to the source driver. The display device further comprises a data bus having a plurality of data lines transmitting display data output from the timing controller to the source driver. The timing controller outputs control signals, which control the source driver, to the source driver via at least one of a plurality of data lines of the second and third buses and the plurality of data lines in a predetermined period of time.

According to an embodiment of the present disclosure, a display device comprises a first bus connected between a timing controller and a source driver, a second bus connected between the timing controller and the source driver, and a data bus connected between the timing controller and the source driver and having a first data line, a second data line, and a third data line. The timing controller generates a clock signal, a first operation control signal, a second operation control signal, and a polarity control signal in a first period of time, and the clock signal, the first operation signal, and the second operation signal in a second period of time. The timing controller outputs the clock signal to the first bus, the first operation control signal to the second bus, the second operation control signal to the first data line, and the polarity control signal to the second data line in the first period of time, and the clock signal to the first bus, the first operation control signal to the second bus, and the second operation control signal to one of the first through third data lines in the second period of time.

A logic level of the first operation control signal input to the second bus is equivalent to a logic level of the second operation control signal input to the first data line in the first period of time, and the logic level of the first operation control signal input to the second bus is different from the logic level of the second operation control signal input to the first data line in the second period of time.

According to an embodiment of the present disclosure, a display device comprises a plurality of source drivers connected in a serial cascade, a first signal transmission unit having a plurality of buses which connects a source driver of the plurality of source drivers and a timing controller, and a second signal transmission unit having a plurality of buses connected between pairs of source drivers.

The first signal transmission unit comprises a first bus transmitting a clock signal output from the timing controller, a second bus transmitting a first operation control signal output from the timing controller, and a first data bus having a plurality of data lines transmitting display data output from the timing controller. At least one of the plurality of data lines transmits a control signal which is output from the timing controller to control the source driver.

The second signal transmission unit comprises a third bus transmitting the clock signal, a fourth bus transmitting the first operation control signal, and a second data bus having a plurality of data lines transmitting display data transmitted through a first source driver of a pair of source drivers connected in the serial cascade to a second source driver of the pair of source drivers. At least one second operation control signal output from the first source driver to control an operation of the second source driver is transmitted to the second source driver via at least one of the plurality of data lines of the second data bus.

According to an embodiment of the present disclosure, a display device comprises a timing controller, a first source driver block having a plurality of source drivers connected in a serial cascade, a second source driver block having a plurality of source drivers connected in the serial cascade, a first group of buses connected between the timing controller and a source driver of the plurality of source drivers of the first source driver block, a second group of buses connected between the timing controller and a first source driver of the plurality of source drivers of the second source driver block, a third group of buses connected between pairs of source drivers of the first source driver block which are connected in a serial cascade, and a fourth group of buses connected between pairs of source drivers of the second source driver block which are connected in a serial cascade.

Each of the first through fourth groups of buses comprises a first signal path along which a clock signal generated by the timing controller is transmitted, a second signal path along which an operation control signal generated by the timing controller is transmitted, and a third signal path with a plurality of data lines which allow transmission of display data generated by the timing controller. The timing controller generates a plurality of control signals which control operations of corresponding source drivers in a predetermined period of time, and at least one of the plurality of control signals is transmitted to a corresponding source driver along the second signal path and via a corresponding data line of the plurality of data lines in the predetermined period of time.

### BRIEF DESCRIPTION OF THE DRAWINGS

The present invention will become more apparent by describing in detail exemplary embodiments thereof with reference to the attached drawings in which:

FIG. 1 is a block diagram of a TFT-LCD;

FIG. 2 is a timing diagram illustrating the operation of the TFT-LCD of FIG. 1;

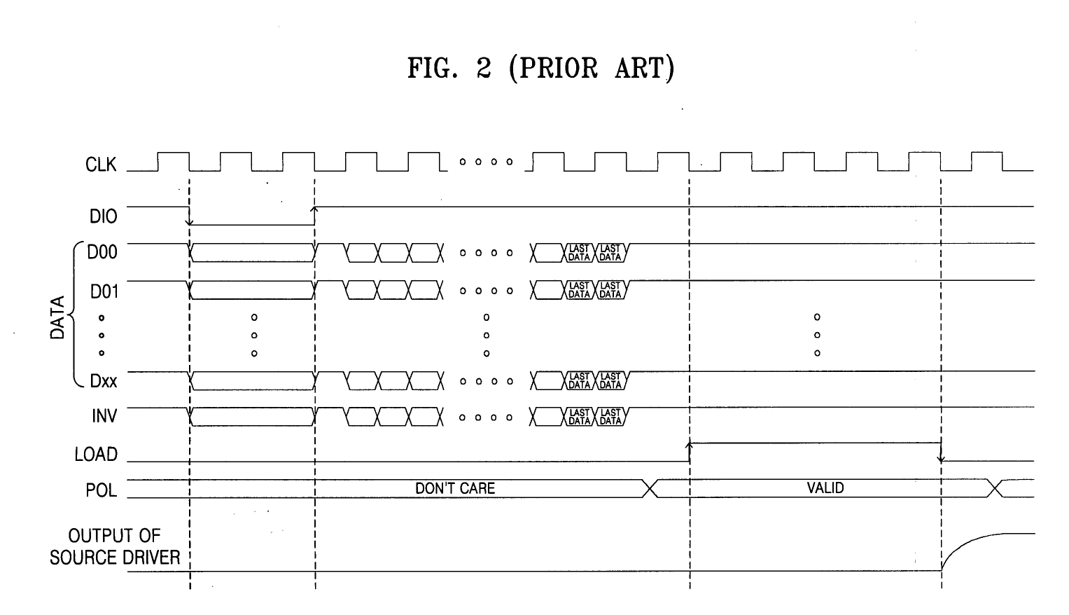

FIG. 3 is a block diagram of a display device according to an embodiment of the present disclosure;

FIG. 4 illustrates connection of buses and source drivers of the display device of FIG. 3 according to an embodiment of the present disclosure;

FIG. 5 is a circuit diagram of a source driver of FIG. 3 according to an embodiment of the present disclosure;

FIG. 6 is a timing diagram illustrating the operation of the display device of FIG. 3 according to an embodiment of the present disclosure;

FIG. 7 illustrates connection of the buses and source drivers of FIG. 3 according to another embodiment of the present disclosure;

FIG. 8 is a circuit diagram of the source driver of FIG. 3 according to another embodiment of the present disclosure;

FIG. 9 is a timing diagram illustrating the operation of the display device of FIG. 3 according to another embodiment of the present disclosure; and

FIG. 10 is a block diagram of a display device according to another embodiment of the present disclosure.

### DETAILED DESCRIPTION OF PREFERRED EMBODIMENTS

Hereinafter, exemplary embodiments of the present invention will be described in detail with reference the accompanying drawings. The same reference numerals represent the same elements throughout the drawings.

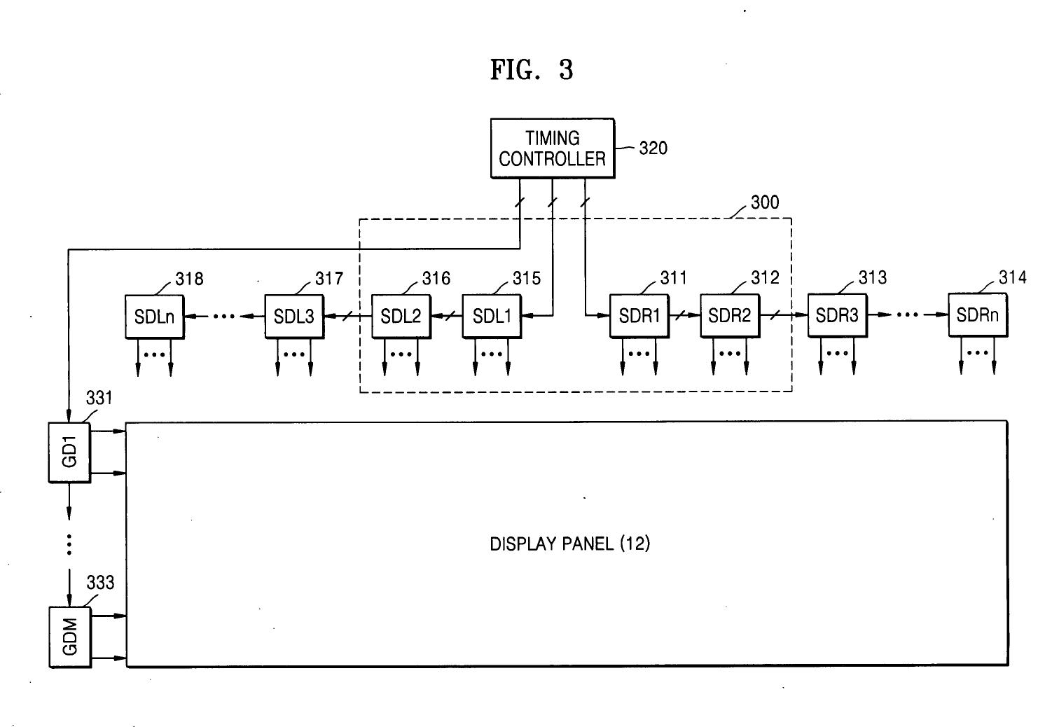

FIG. 3 is a block diagram of a display device according to an embodiment of the present disclosure. The display device includes a display panel 12, a timing controller 320, a plurality of source driver blocks, and a gate driver block with a plurality of gate drivers 331, . . . , 333. A first source driver block includes a plurality of source drivers 311, 312, 313, . . . , 314, and a second source driver block includes a plurality of source drivers 315, 316, 317, . . . , 318.

A display device according to the present invention may be embodied as an active matrix type TFT-LCD but is not limited to the active matrix type TFT-LCD.

The source drivers 311, 312, 313, . . . , 314 are connected in serial cascade form, and the source drivers 315, 316, 317, . . . , 318 are also connected in serial cascade form. Further, the plurality of gate drivers 331, . . . , 333 are connected in serial cascade form.

The plurality of source drivers 311 through 318 drive corresponding data lines of the display panel 12, and the plurality of gate drivers 331, . . . , 333 drive corresponding scan lines of the display panel 12.

The first and second source driver blocks are preferably installed on the display panel 12 so that they are symmetrical to each other with respect to the timing controller 320. Such a structure in which the first and second source driver blocks are installed is referred to as a T-type serial cascade. The construction of a display device according to the present disclosure is not limited to the T-type serial cascade.

As shown in FIG. 3, the serial cascade according to the present disclosure indicates a structure in which only the source drivers 311 and 315 receive various signals output from the timing controller 320, and the source drivers 312 through 314 and 316 through 318 receive the outputs of the source driver 311 and the source driver 315, respectively.

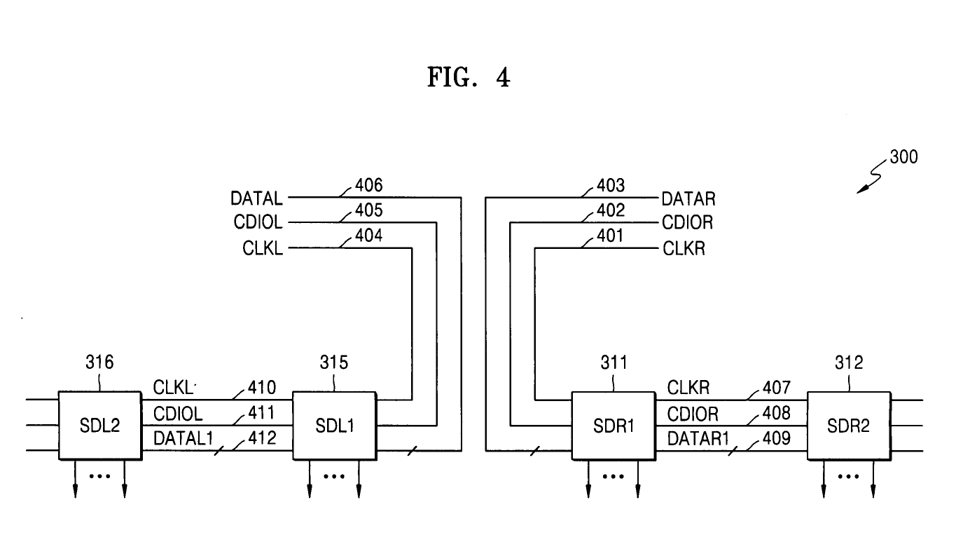

FIG. 4 illustrates connection of buses and the source drivers 311 through 314 and 315 through 318 of FIG. 3 according to an embodiment of the present disclosure. FIG. 4 illustrates the construction of a portion of FIG. 3 in detail.

Referring to FIGS. 3 and 4, buses 401 through 403 are connected between the timing controller 320 and the source driver 311, buses 404 through 406 are connected between the timing controller 320 and the source driver 315, buses 407 through 409 are connected between the source driver 311 and the source driver 312, and buses 410 through 412 are connected between the source driver 315 and the source driver 316.

The buses 401 and 407 transmit a clock signal CLKR, the buses 404 and 410 transmit a clock signal CLKL, the buses 402 and 408 transmit an operation control signal CDIOR, and the buses 405 and 411 transmit an operation control signal CDIOL. The clock signals CLKR and CLKL preferably indicate the same signal, and the operation control signals CDIOR and CDIOL preferably indicate the same signal.

The buses 403, 406, 409, and 412 are used to transmit display data DATAR, DATAL, DATAR1, and DATAL1 to the corresponding source drivers 311, 315, 312, and 316, respectively. Each of the buses 403, 406, 409, and 412 includes a plurality of data lines.

The display device of FIG. 4 according to the present disclosure does not have a signal line for transmitting a polarity control signal POL and a signal line for transmitting a load signal LOAD.

The source drivers 311 through 318 recognize a data initiation signal and a load signal, based on a combination of the logic level of a signal transmitted from the timing controller 320 to the buses 402 and 405 and the logic level of signal transmitted to a first data line of a plurality of data lines of the buses 403 and 406 in a predetermined period of time.

The timing controller 320 outputs the polarity control signal POL to a second data line of the plurality of data lines of each of the buses 403 and 406 for a predetermined period of time. The polarity control signal POL is transmitted to the source drivers 311 and 315 via the second data lines, through which display data are not transmitted.

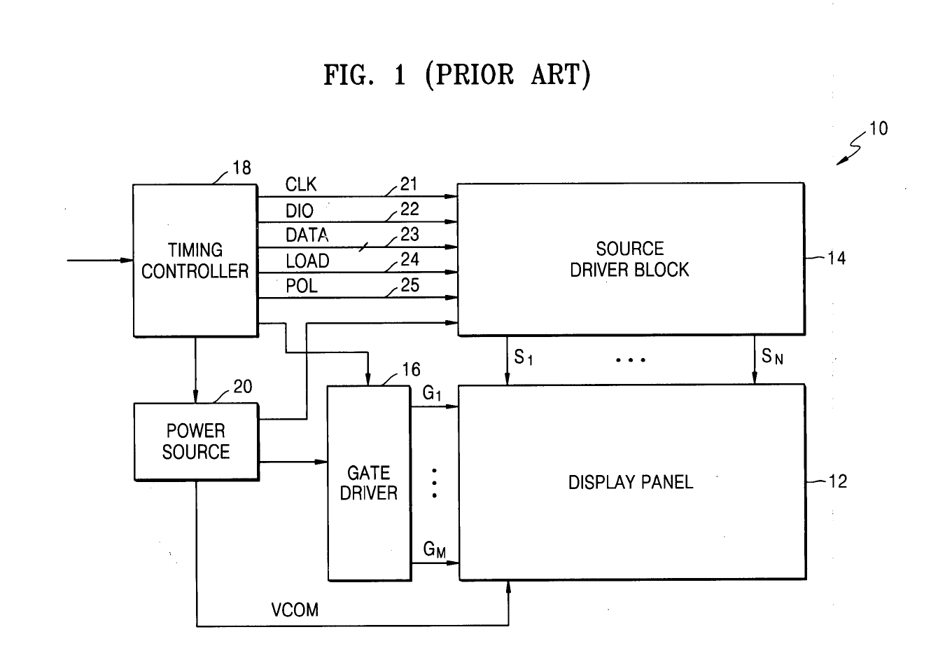

A display device according to an embodiment of the present disclosure needs a reduced number of buses, or data lines, than a display device according to FIG. 1, thereby reducing the amount of current consumed, and the occurrence of electromagnetic interference (EMI) generated by, the display device.

Here, various signals CLKR, CLKL, CDIOR, CDIOL, DATAR, DATAL, DATAR1, and DATAL1 transmitted to the respective buses 401 through 412 are single ended signals.

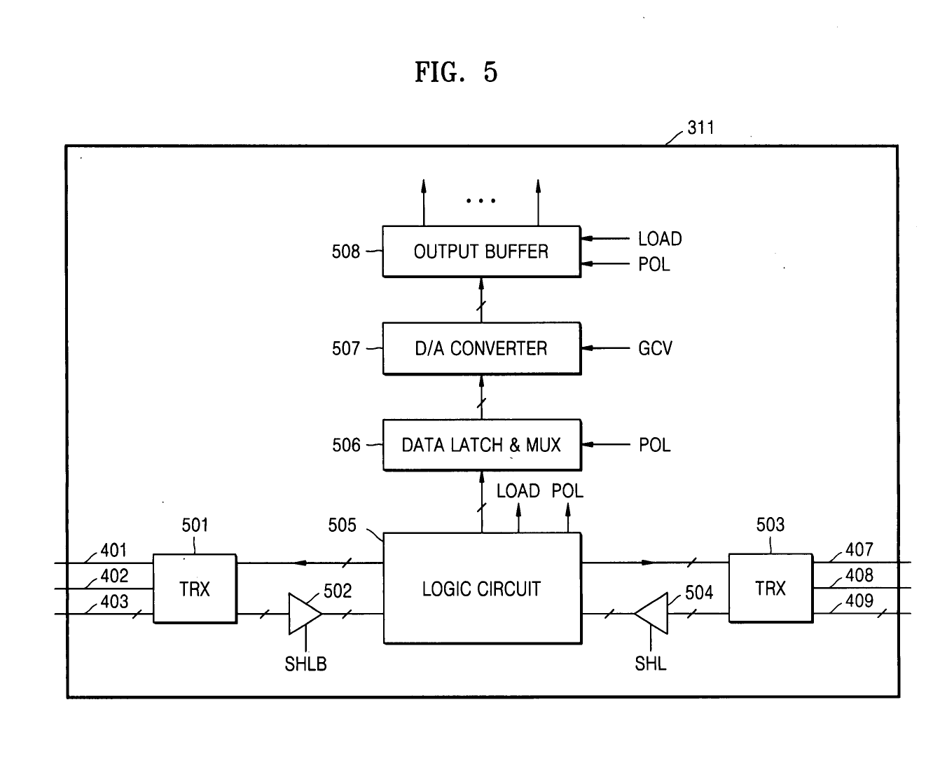

FIG. 5 is a circuit diagram of the source driver 311 of FIG. 3 according to an embodiment of the present disclosure. Referring to FIGS. 3 and 5, the source drivers 311 through 318 are bi-directional source drivers. The source driver 311 transmits the signals CLKR, CDIOR, and DATAR output from the timing controller 320 to the source driver 312, and the source driver 315 transmits the signals CLKL, CDIOL, and DATAL output from the timing controller 320 to the source driver 316. The construction of the source driver 311 is substantially similar to those of the source drivers 312 through 318.

The source driver 311 includes a first transceiver 501, a first input buffer 502, a second transceiver 503, a second input buffer 504, a logic circuit 505, a data latch & multiplexer 506, a digital-to-analog (D/A) converter 507, and an output buffer 508.

Directions in which the first input buffer 502, the second input buffer 504, and the logic circuit 505 transmit signals are determined by the logic levels of control signals SHL and SHLB output from the timing controller 320.

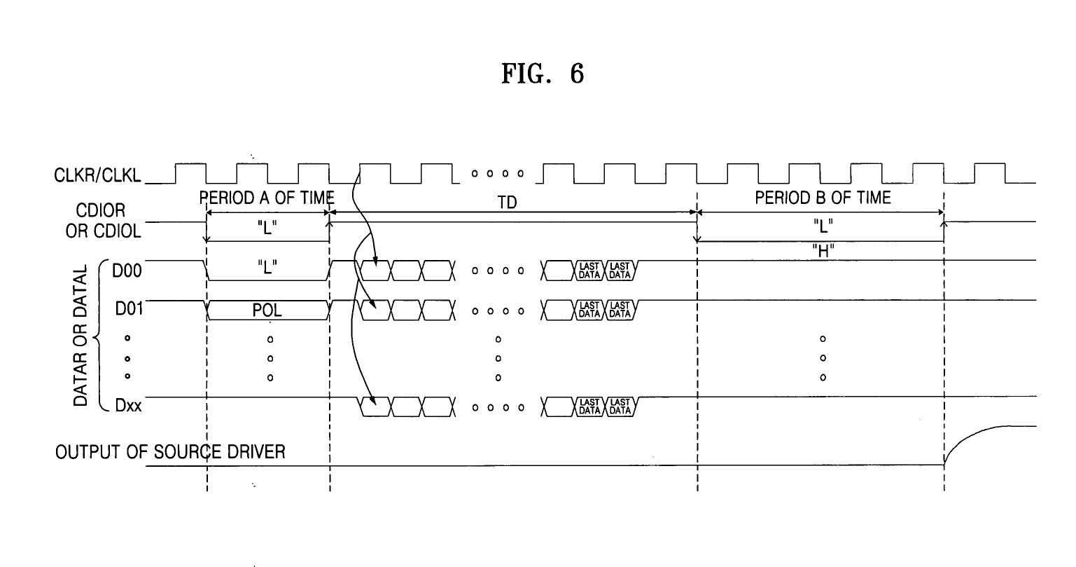

FIG. 6 is a timing diagram illustrating the operation of the display device of FIG. 3 according to an embodiment of the present disclosure. The operations of the source drivers 311 through 318 will now be described with reference to FIGS. 3 through 6. Each of the buses 403, 406, 409, and 412 includes a plurality of data lines D00 through Dxx (xx is an integer greater than or equal to 1).

Referring to FIG. 6, in a period of time A, the timing controller 320 generates the clock signal CLKR, the first operation control signal CDIOR, the second operation control signal (not shown), and the polarity control signal POL.

In the period of time A, the timing controller 320 transmits the clock signal CLKR to the source driver 311 via the bus 401, transmits the first operation control signal CDIOR, which has a logic low level L, to the source driver 311 via the bus 402, transmits the second operation control signal to the source driver 311 via the first data line D00 of the plurality of data lines of the bus 403, and transmits the polarity control signal POL to the source driver 311 via the second data line D01 of the plurality of data lines D00 through Dxx.

The first input buffer 502 is enabled in response to the control signal SHLB and transmits CLKR, CDIOR, and DATAR input via the buses 401, 402 and 403 and the first transceiver 501 to the logic circuit 505. In this case, the second input buffer 504 is disabled in response to the control signal SHL. The control signals SHL and SHLB are preferably complementary signals.

In the period of time A, when the first operation control signal CDIOR and the second operation control signal are low, the logic circuit 505 outputs a data initiation signal (not shown). The logic circuit 505 receives and latches the polarity control signal POL. The polarity control signal POL is used to determine the output polarity of latched display data.

In a display data transmission interval TD, the timing controller 320 transmits the clock signal CLKR to the source driver 311 via the first bus 401, the first operation control signal CDIOR that is logic high (H) to the source driver 311 via the second bus 402, and the display data DATAR to the source driver 311 via the data lines D00 through Dxx.

The logic circuit 505 outputs the received display data DATAR to the data latch & multiplexer 506. The data latch & multiplexer receives and latches the display data DATAR allocated to the source driver 311 in synchronization with a rising edge and a falling edge of the clock signal CLKR. The D/A converter 507 converts the display data DATAR into analog signals in response to a gamma compensation voltage GCV.

Before the data latch & multiplexer 506 completely latches the display data DATAR allocated to the source driver 311, in the display data transmission interval TD, the source driver 311 generates the first operation control signal CDIOR that is logic low (L) and transmits it to the source driver 312 via the bus 408. The source driver 311 also generates the second operation control signal that goes logic low (L) and transmits it to the source driver 312 via the first data line D00 of the plurality of data lines of the bus 409, and generates the latched polarity control signal POL and transmits it to the source driver 312 via the second data line D01 of the plurality of data lines.

The source driver 312 receives the first operation control signal CDIOR and the second operation control signal which are logic low (L), and receives the display data DATAR1 allocated to the source driver 312. The source driver 312 latches the allocated display data DATAR in synchronization with the rising and falling edges of the clock signal CLKR.

The clock signal CLKR is transmitted to the source driver 312 via the bus 407. The source driver 311 generates the first operation control signal CDIOR and transmits it to the source driver 312 via the bus 408, generates the second operation control signal and transmits it to the source driver 312 via the first data line D00 of the plurality of data lines of the bus 409, and generates the polarity control signal POL and transmits it to the source driver 312 via the second data line D01 of the plurality of data lines. Accordingly, the source driver 312 receives and stores the allocated display data DATAR1 in the display data transmission interval TD.

Similarly, in the display data transmission interval TD, the source drivers 311 through 318 receive and store display data allocated thereto.

The source drivers 311 through 318 store the display data in synchronization with both the rising and falling edges of the clock signals CLKR and CLKL.

After the display data allocated to the respective source drivers 311 through 318 are stored in the source drivers, in an interval B, the first operation control signal CDIOR or CDIOL output from the timing controller 320 to each of the source drivers 311 through 318 via the corresponding buses 402, 405, 408, and 411 goes logic low (L). The second operation control signal output from the timing controller 320 to the source drivers 311 through 318 via one of the data lines of each of the corresponding buses 403, 406, 409, and 412 goes logic high (H).

A logic circuit of each of the source drivers 311 through 318 outputs a load signal LOAD having a logic high (H) level when the first operation control signal CDIOR or CDIOL goes logic low (L) and the second operation control signal goes logic high (H).

The source drivers 311 through 318 drive corresponding data lines of the display panel 12 using the display data DATAR1 or DATAL1 in response to the polarity control signal POL and the load signal LOAD. Thus, the display data DATAR1 and DATAL1 are displayed on the display panel 12. The polarity control signal POL is latched in the logic circuits of the source drivers 311 through 318 until a new polarity control signal is input.

Table 1 shows signals recognized or generated based on the logic levels of a combination of control signals generated in various intervals according to an embodiment of the present disclosure.

TABLE 1

| | | CDIOR or | | | Other Data |
|---|---|---|---|---|---|
| Function | Interval | CDIOL | D00 | D01 | Lines |
| Data | A | Low | Low | Don't care | Don't care |
| Initiation | | | | | |
| signal | | | | | |
| Polarity | A | Low | Low | POL | Don't care |
| Control | | | | Characteristics | |
| Signal | | | | | |
| Load Signal | B | Low | High | Don't care | Don't care |

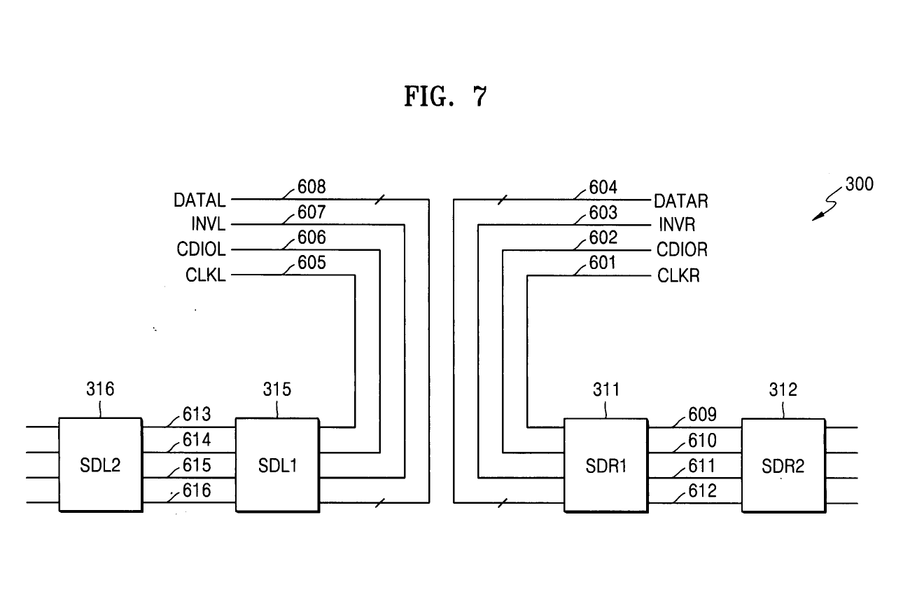

FIG. 7 illustrates connections of the buses 601 through 616 and the source drivers 311 through 318 of FIG. 3 according to another embodiment of the present disclosure. Referring to FIG. 7, signals transmitted from the timing controller 320 to the corresponding buses 601 through 616 are differential signals. A display device may use a data inversion signal INV to reduce the amount of current consumed.

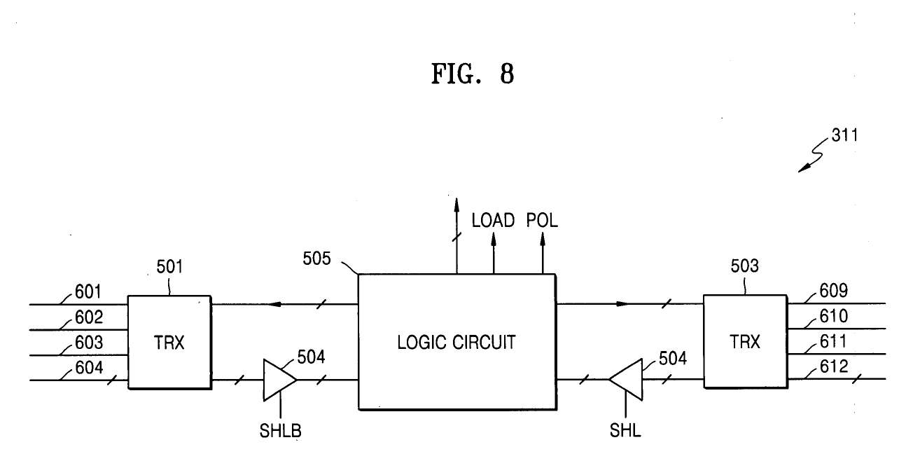

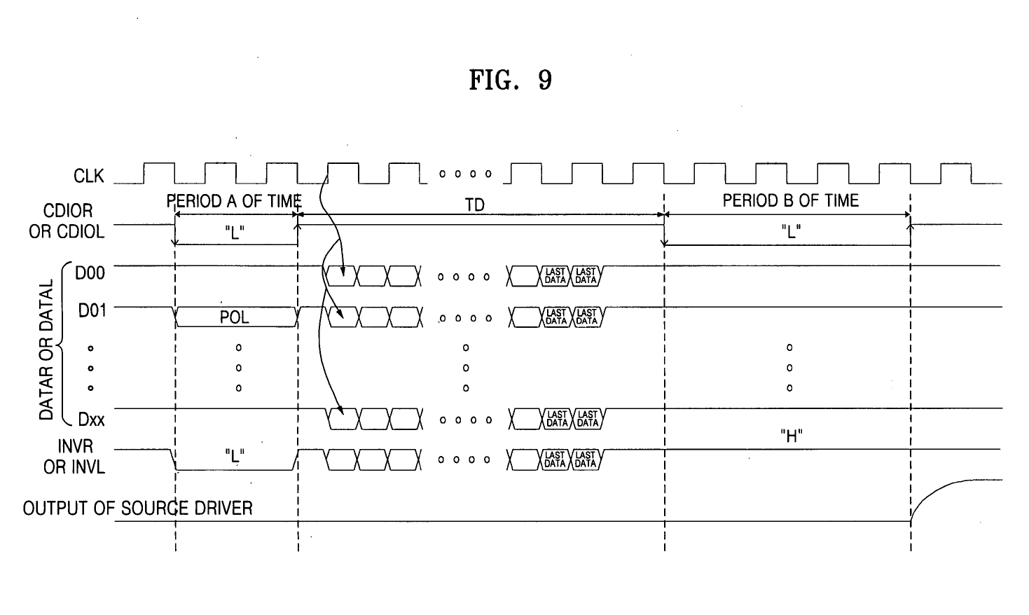

FIG. 8 is a circuit diagram of the source driver 311 of FIG. 3. Referring to FIGS. 7 and 3, transceivers 501 and 503 are connected to buses 601 through 604 and 609 through 612, respectively. FIG. 9 is a timing diagram illustrating the operation of the display device of FIG. 3 according to the embodiment of the present disclosure in FIGS. 7 and 8.

Referring to FIGS. 3 and 7 through 9, the buses 601 through 604 are connected between the timing controller 320 of FIG. 3 and the source driver 311, the buses 605 through 608 are connected between the timing controller 320 and the source driver 315, the buses 609 through 612 are connected between the source driver 311 and the source driver 312, and the buses 605 through 608 are connected between the source driver 315 and the source driver 316.

The buses 601 and 609 transmit a clock signal CLKR, and the buses 605 and 613 transmit a clock signal CLKL. The clock signal CLKR transmitted to the source drivers 311, . . . , 314 on the right of a logic circuit 505, and the clock signal CLKL transmitted to the source drivers 315, . . . 318 on the left of the logic circuit 505 are preferably the same type of signals.

The buses 602 and 610 transmit a control signal CDIOR, and the buses 606 and 614 transmit a control signal CDIOL. The control signal CDIOR related to the source drivers 311, . . . , 314 on the right of the logic circuit 505, and the control signal CDIOL related to the source drivers 315, . . . 318 on the left of the logic circuit 505 are preferably the same type of signals.

The buses 603 and 611 transmit a second operation control signal or the data inversion signal INVR, and the buses 607 and 615 transmit a second operation control signal or the data inversion signal INVL.

Referring to FIGS. 7 and 9, the buses 603, 607, 611 and 615 transmit the second operation control signal in intervals A and B. The buses 603, 607, 611, and 615 transmit the data inversion signal INVR or INVL in a display data transmission interval TD.

Each of the buses 604, 608, 612, and 616 includes a plurality of data lines D00 through Dxx (where xx is an integer greater than or equal to 1). In the period of time A, the data line D01 of each of the buses 604, 608, 612, and 616 allows a polarity control signal POL to be transmitted to the source driver 311 or 315. In the display data transmission period of time TD, the buses 604, 608, 612, and 616 transmit display data allocated to the source drivers 311 through 318 to the source drivers 311 through 318, respectively.

In display data transmission interval TD, source drivers 311 and 315 generate new first operation control signals CDIOR and CDIOL, for use by the source drivers 312 and 316, using the first operation control signals CDIOR and CDIOL received in the interval A, respectively. The generated new first operation control signals CDIOR and CDIOL are output to the source drivers 312 and 316 via their corresponding buses 610 and 614, respectively.

The source drivers 311 and 315 generate new polarity control signals POL, for use by the source drivers 312 and 316, using the polarity control signal POL received in the interval A. The generated new polarity control signals POL are output to the source drivers 312 and 316 via one of each of the corresponding data buses 612 and 616.

The source drivers 311 and 315 generate new second operation control signals, for use by the source drivers 312 and 316, using the second operation control signal received via the bus 603 in the interval A. The generated new second operation controls signals are output to the source drivers 312 and 316 via the corresponding buses 611 and 615.

The generated first operation control signals CDIOR and CDIOL, polarity control signals POL, and second operation control signals are preferably transmitted simultaneously in the interval A. Theses signals are preferably transmitted to the source drivers 312 and 316, respectively, before the display data DATAR and DATAL allocated to the source drivers 312 and 316 are transmitted from the source drivers 312 and 316 to the source drivers 312 and 316, respectively.

After the display data DATAR or DATAL allocated to the source drivers 311 through 318 are stored in the source drivers 311 through 318, in an interval B, the first operation control signal CDIOR or CDIOL output from the timing controller 320 to the source drivers 311 through 318 via the corresponding buses 602, 606, 610, and 614 goes logic low (L), and the second operation control signal output from the timing controller 320 to the source drivers 311 through 318 via the corresponding buses 603, 607, 611, and 615 goes logic high (H).

A logic circuit of each of the source drivers 311 through 318 output the load signal LOAD when the first operation control signal CDIOR or CDIOL goes logic low (L) and the second operation control signal goes logic high (H).

Each of the source drivers 311 through 318 drive the data lines D00 through Dxx of the display panel 12 in response to the polarity control signal POL and the load signal LOAD. Therefore, the display data DATAR and DATAL are displayed on the display panel 12. The timing controller 320 and the source drivers 311 through 318 share information regarding rules of transmission of signals, such as the first operation control signals CDIOR and CDIOL, the second operation control signal, and the polarity control signal POL, and information regarding the buses, or corresponding data lines, 601 through 616 through which these signals are transmitted.

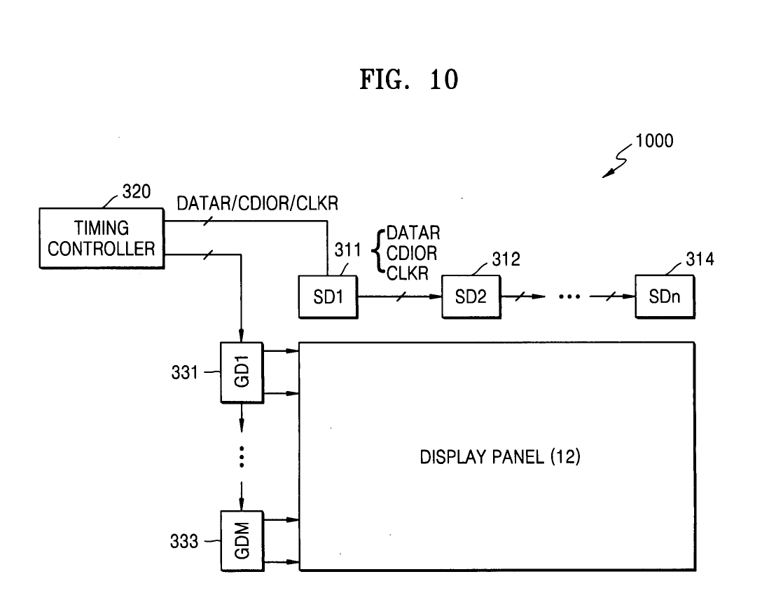

FIG. 10 is a block diagram of a display 1000 according to an embodiment of the present disclosure. The display device 1000 includes a timing controller 320, n source drivers 311, 312, . . . , 314 (n is a natural number), and m gate drivers 331, . . . , 333 (m is a natural number).

The n source drivers 311, 312, . . . , 314 are connected in a serial cascade form. The constructions of buses (not shown) connected between the timing controller 320 and the source driver 311 are substantially similar to those of buses 601 through 604 connected between the timing controller 320 and the source driver 311 of FIGS. 4 and 7. If another bus is connected between the timing controller 320 and the source driver 311 for transmission of a data inversion signal, another bus may be connected between the n source drivers 311, 312, . . . , 314 for transmission of the data inversion signal.

The construction of buses connected between the source drivers 311 and 312 is substantially similar to that of the buses 601 through 604 connected between the timing controller 320 and the source driver 311 of FIGS. 4 and 7.

Accordingly, those having ordinary skill in the art can understand the operation of the display device 1000 from the timing diagrams of FIGS. 6 and 9.

As described above, a display device with a bus construction according to an embodiment of the present disclosure needs fewer buses connected between a timing controller and a source driver than a display device as illustrated in FIG. 1, thereby reducing the amount of current consumed by the display device. Also, the occurrence of EMI generated by the display device can be reduced.

A reduction in the number of buses allows the thicknesses of, or distances between, wirings to be effectively adjusted or reduced. Further, in the case of a display device that operates in response to a current, a reduction in panel wiring resistance improves the performance of the display device.

While this invention has been particularly shown and described with reference to exemplary embodiments thereof, it will be understood by those skilled in the art that various changes in form and details may be made therein without departing from the spirit and scope of the invention as defined by the appended claims.

1. A display device comprising:
a first bus transmitting a clock signal output from a timing controller to a source driver;
a second bus transmitting a first operation control signal output from the timing controller to the source driver; and
a data bus having a plurality of data lines transmitting display data output from the timing controller to the source driver,
wherein the timing controller outputs control signals to the source driver via the second bus and at least one of the plurality of data lines in a predetermined period of time, wherein the control signals control the source driver.

2. The display device of claim 1, wherein the clock signal, the first operation control signal, and the display data transmitted from the first bus, the second bus, and the data bus, respectively, are single-ended signals.

3. The display device of claim 1, further comprising a third bus transmitting a data inversion signal output from the timing controller to the source driver.

4. The display device of claim 1, wherein the clock signal, the first operation control signal, and the display data transmitted from the first bus, the second bus, and the data bus, respectively, are differential signals.

5. The display device of claim 1, wherein the timing controller outputs a second operation control signal to the source driver via a first data line of the plurality of data lines, wherein the second operation control signal has a logic level maintained to be equivalent to a logic level of the first operation control signal in the predetermined period of time.

6. The display device of claim 5, wherein the source driver latches the display data in response to the first and second operation control signals.

7. The display device of claim 5, wherein the timing controller outputs a polarity control signal to the source driver via a second data line of the plurality of data lines in the predetermined period of time, and
the source driver controls the polarity of the display data to be output, in response to the polarity control signal.

8. The display device of claim 1, wherein the timing controller outputs a second operation control signal to the source driver via the first data line of the plurality of data lines, wherein the second operation control signal has a logic level maintained to be different from a logic level of the first operation control signal during the predetermined period of time.

9. The display device of claim 8, wherein the source driver outputs display data in response to the polarity control signal and the first and second operation control signals.

10. The display device of claim 1, further comprising a third bus transmitting a data inversion signal output from the timing controller to the source driver,
wherein the timing controller outputs control signals to the source driver via at least one of a plurality of data lines of the second and third buses and the plurality of data lines during the predetermined period of time, wherein the control signals control the source driver.

11. The display device of claim 10, wherein the timing controller outputs a polarity control signal to the source driver via at least one of the plurality of data lines.

12. The display device of claim 10, wherein the first operation control signal and the data inversion signal output from the timing controller to the source driver have the same logic level during the predetermined period of time.

13. The display device of claim 10, wherein the first operation control signal and the data inversion signal output from the timing controller to the source driver have different logic levels during the predetermined period of time.

14. The display device of claim 1, wherein
the first bus is connected between the timing controller and the source driver;
the second bus is connected between the timing controller and the source driver; and
the data bus connected between the timing controller and the source driver, the data bus having a first data line, a second data line, and a third data line of the plurality of data lines,
wherein the timing controller generates the control signals including a clock signal, a first operation control signal, a second operation control signal, and a polarity control signal in a first period of time, and the control signals including the clock signal, the first operation signal, and the second operation signal in a second period of time, and
outputs the clock signal to the first bus, the first operation control signal to the second bus, the second operation control signal to the first data line, and the polarity control signal to the second data line in the first period of time, and the clock signal to the first bus, the first operation control signal to the second bus, and the second operation control signal to one of the first through third data lines in the second period of time.

15. The display device of claim 14, wherein a logic level of the first operation control signal input to the second bus is equivalent to a logic level of the second operation control signal input to the first data line in the first period of time, and
the logic level of the first operation control signal input to the second bus is different from the logic level of the second operation control signal input to the first data line in the second period of time.

16. The display device of claim 14, wherein the timing controller generates display data, and outputs the display data to the source driver via the data bus in a display data transmission period of time between the first and second periods of time.

17. The display device of claim 14, wherein the clock signal, the first operation control signal, and the second operation control signal output to the first bus, the second bus, and the data bus, respectively, are single-ended signals.

18. The display device of claim 14, comprising:
a third bus connected between the timing controller and the source driver,
wherein the timing controller outputs the clock signal to the first bus, the first operation control signal to the second bus, the second operation control signal to the third bus, and the polarity control signal to one of the plurality of data lines in the first period of time, and the clock signal to the first bus, the first operation control signal to the second bus, and the second operation control signal to the third bus in the second period of time.

19. The display device of claim 18, wherein a logic level of the first operation control signal is equivalent to a logic level of the second operation control signal in the first period of time, and
the logic level of the first operation control signal is different from the logic level of the second operation control signal in the second period of time.

20. The display device of claim 18, wherein the timing controller generates display data and a data inversion signal, and
transmits the display data to the source driver via the data bus and the data inversion signal to the source driver via the third bus in a display data transmission period of time between the first and second periods of time.

21. The display device of claim 18, wherein the clock signal, the first operation control signal, and the second operation control signal output to the first bus, the second bus, and the third bus, respectively, are differential signals.

22. A display device comprising:
a plurality of source drivers connected in a serial cascade;
a first signal transmission unit having a plurality of buses connected between a source driver of the plurality of source drivers and a timing controller; and
a second signal transmission unit having a plurality of buses connected between pairs of source drivers.

23. The display device of claim 22, wherein the first signal transmission unit comprises:
a first bus transmitting a clock signal output from the timing controller;
a second bus transmitting a first operation control signal output from the timing controller; and
a first data bus having a plurality of data lines transmitting display data output from the timing controller,
wherein at least one of the plurality of data lines transmits a control signal output from the timing controller to control the source driver.

24. The display device of claim 23, wherein the timing controller generates a plurality of control signals in a predetermined period of time,
and transmits the first operation control signal to the first bus, a second operation control signal of the plurality of control signals to a first data line of the plurality of data lines, and a third operation control signal of the plurality of control signals to a second data line of the plurality of data lines.

25. The display device of claim 23, wherein the timing controller generates a plurality of control signals in a predetermined period of time,
and transmits the first operation control signal to the first bus and a second operation control signal of the plurality of control signals to one of the plurality of data lines.

26. The display device of claim 23, wherein the second signal transmission unit comprises:
a third bus transmitting the clock signal;
a fourth bus transmitting the first operation control signal; and
a second data bus having a plurality of data lines transmitting display data through a first source driver of a pair of source drivers connected in the serial cascade to a second source driver of the pair of source drivers,
wherein at least one second operation control signal output from the first source driver to control an operation of the second source driver is transmitted to the second source driver via at least one of the plurality of data lines of the second data bus.

27. The display device of claim 22, further comprising:
a timing controller;
a first source driver block having a first plurality of the plurality of source drivers connected in a serial cascade;
a second source driver block having a second plurality of the plurality of source drivers connected in a serial cascade;
a first group of buses of the first signal transmission unit connected between the timing controller and a source driver of the plurality of source drivers of the first source driver block;
a second group of buses of the first signal transmission unit connected between the timing controller and a first source driver of the plurality of source drivers of the second source driver block;
a third group of buses of the second signal transmission unit connected between pairs of source drivers of the first source driver block; and
a fourth group of buses of the second signal transmission unit connected between pairs of source drivers of the second source driver block.

28. The display device of claim 27, wherein each of the first through fourth groups of buses comprises:
a first signal path along which a clock signal generated by the timing controller is transmitted;
a second signal path along which an operation control signal generated by the timing controller is transmitted; and
a third signal path comprising a plurality of data lines transmitting display data generated by the timing controller,
wherein the timing controller generates a plurality of control signals which control operations of corresponding source drivers in a predetermined period of time, and
at least one of the plurality of control signals is transmitted to a corresponding source driver along the second signal path and via a corresponding data line of the plurality of data lines in the predetermined period of time.

29. A display device comprising:
a first bus transmitting a first clock signal output from a timing controller to a first source driver;
a second bus transmitting a first operation control signal output from the timing controller to the first source driver;
a first data bus having a plurality of data lines transmitting a first display data output from the timing controller to the first source driver;
a third bus transmitting a second clock signal output from the timing controller to a second source driver;
a fourth bus transmitting a second operation control signal output from the timing controller to the second source driver; and
a second data bus having a plurality of data lines transmitting a second display data output from the timing controller to the second source driver,
wherein the timing controller outputs first control signals to the first source driver via the second bus and at least one of the plurality of data lines of the first data bus in a predetermined period of time, wherein the first control signals control an operation of the first source driver, and
outputs second control signals to the second source driver via the fourth bus and at least one of the plurality of data lines of the second data bus in the predetermined period of time, wherein the second control signals control an operation of the second source driver.

30. The display device of claim 29, wherein the first clock signal and the second clock signal indicate the same signal, and the first operation control signal and the second operation control signal indicate the same signal.
